(19) United States
(12) Patent Application Publication
(10) Pub. No.: US 2009/0242030 A1
(43) Pub. Date: Oct. 1, 2009

(54) HIGH PERFORMANCE ANTI-SPALL LAMINATE ARTICLE

(75) Inventors: CYNTHIA H. KIRSCHNER, Beaumont, TX (US); Jerrel C. Anderson, Vienna, WV (US); Stephen J. Bennison, Wilmington, DE (US); Richard Allen Hayes, Beaumont, TX (US); David F. Kristunas, Townsend, DE (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E. I. DU PONT DE NEMOURS AND COMPANY, Wilmington, DE (US)

(21) Appl. No.: 12/411,863

(22) Filed: Mar. 26, 2009

Related U.S. Application Data
(60) Provisional application No. 61/070,800, filed on Mar. 26, 2008.

(51) Int. Cl. H01L 31/0256

(52) U.S. Cl. 136/260; 136/261; 136/262; 136/263; 136/264; 136/265; 428/480

(57) ABSTRACT

Provided is a high performance anti-spall laminate article comprising a bi-layer polymeric composite. The bi-layer composite includes a polymeric sheet and a poly(ethylene terephthalate) (PET) film laminated to each other. The PET film has a tensile modulus of about 600,000 psi or higher in both the machine direction (MD) and the transverse direction (TD), a shock brittleness index of about 55 Joules or higher in the machine direction and about 25 joules or higher in the transverse direction, and a percent elongation at break (EOB) of about 110-160 in the machine direction and about 60-110 in the transverse direction.

### CROSS-REFERENCE TO RELATED APPLICATION

The present application claims priority under 35 U.S.C. §120 to U.S. Provisional Appln. No. 61/070,800, filed on Mar. 26, 2008, which is incorporated herein by reference in its entirety.

### FIELD OF THE INVENTION

Provided herein is a laminate article, such as a glazing laminate or a solar cell module, having improved anti-spall performance. In particular, the laminate article incorporates a poly(ethylene terephthalate) film that is characterized by a favorable balance of tensile modulus, shock brittleness index, and elongation.

### BACKGROUND OF THE INVENTION

Laminated safety glass has been used in windows and windshields of buildings and automobiles since the late 1930's. The laminated safety glass typically consists of a sandwich of two glass sheets or panels bonded together by an interlayer formed of polymeric film(s) or sheet(s). One or both of the glass sheets in the sandwich may be replaced by an optically clear rigid polymer sheet or a hard-coated polymeric film. Such a design may be called for when a lighter construction is desired, for example, or when the window will be subject to asymmetrical wear, or in an application in which the required level of resistance to physical insults is different from that provided by glass.

One typical glass/plastic laminate comprises a hard-coated polyester film bonded to a glass sheet by a polymeric interlayer. The glass/plastic laminate may be formed by laminating a pre-formed bi-layer composite sheet to the glass sheet. One example of a pre-formed bi-layer composite is commercially available from E. I. du Pont de Nemours and Company of Wilmington, Del. (hereinafter “DuPont”), under the trademark Spallshield®. In a Spallshield® composite, the hard-coated polyester film is bonded to a poly(vinylbutyral) (PVB) interlayer sheet.

As their use in the glazing laminate industry becomes more widespread, glass/plastic laminates are required to meet ever increasing demands on their performance. Some of these demands are for glass/plastic laminates that splinter less upon impact or that possess increased impact resistance.

### SUMMARY OF THE INVENTION

Described herein is laminate article comprising a bi-layer composite and, optionally, one or more additional laminate layers, wherein the bi-layer composite consists essentially of a polymeric sheet and a poly(ethylene terephthalate) (PET) film laminated to each other. The PET film has (i) a tensile modulus of about 600,000 psi or higher in both the machine direction (MD) and the transverse direction (TD); (ii) a shock brittleness index of about 55 Joules or higher in the MD and about 25 joules or higher in the TD; and (iii) a percent elongation at break (EOB) of about 110 to 160 or 170 in the MD and about 60 to 110 in the TD.

### DETAILED DESCRIPTION OF THE INVENTION

Several patents and publications are cited in this description in order to more fully describe the state of the art to which this invention pertains. The entire disclosure of each of these patents and publications is incorporated by reference herein.

The following definitions apply to the terms as used throughout this specification, unless otherwise limited in specific instances.

The technical and scientific terms used herein have the meanings that are commonly understood by one of ordinary skill in the art to which this invention belongs. In case of conflict, the present specification, including the definitions herein, will control.

As used herein, the terms “comprises,” “comprising,” “includes,” “including,” “containing,” “characterized by,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The transitional phrase “consisting of” excludes any element, step, or ingredient not specified in the claim, closing the claim to the inclusion of materials other than those recited except for impurities ordinarily associated therewith. When the phrase “consists of” appears in a clause of the body of a claim, rather than immediately following the preamble, it limits only the element set forth in that clause; other elements are not excluded from the claim as a whole.

The transitional phrase “consisting essentially of” limits the scope of a claim to the specified materials or steps and those that do not materially affect the basic and novel characteristic(s) of the claimed invention. A ‘consisting essentially of’ claim occupies a middle ground between closed claims that are written in a ‘consisting of’ format and fully open claims that are drafted in a ‘comprising’ format. Optional additives as defined herein, at a level that is appropriate for such additives, and minor impurities are not excluded from a composition by the term “consisting essentially of”.

When a composition, a process, a structure, or a portion of a composition, a process, or a structure, is described herein using an open-ended term such as “comprising,” unless otherwise stated the description also includes an embodiment that “consists essentially of” or “consists of” the elements of the composition, the process, the structure, or the portion of the composition, the process, or the structure.

The articles “a” and “an” may be employed in connection with various elements and components of compositions, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

The term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such.

The term “or”, as used herein, is inclusive; that is, the phrase “A or B” means “A, B, or both A and B”. More specifically, a condition “A or B” is satisfied by any one of the following: A is true (or present) and B is false (or not present); A is false (or not present) and B is true (or present); or both A and B are true (or present). Exclusive “or” is designated herein by terms such as “either A or B” and “one of A or B”, for example.

In addition, the ranges set forth herein include their endpoints unless expressly stated otherwise. Further, when an amount, concentration, or other value or parameter is given as a range, one or more preferred ranges or a list of upper preferable values and lower preferable values, this is to be understood as specifically disclosing all ranges formed from any pair of any upper range limit or preferred value and any lower range limit or preferred value, regardless of whether such pairs are separately disclosed. The scope of the invention is not limited to the specific values recited when defining a range.

When materials, methods, or machinery are described herein with the term “known to those of skill in the art”, “conventional” or a synonymous word or phrase, the term signifies that materials, methods, and machinery that are conventional at the time of filing the present application are encompassed by this description. Also encompassed are materials, methods, and machinery that are not presently conventional, but that will have become recognized in the art as suitable for a similar purpose.

Unless stated otherwise, all percentages, parts, ratios, and like amounts, are defined by weight.

As used herein, the term “copolymer” refers to polymers comprising copolymerized units resulting from copolymerization of two or more comonomers. In this connection, a copolymer may be described herein with reference to its constituent comonomers or to the amounts of its constituent comonomers, for example “a copolymer comprising ethylene and 15 weight % of acrylic acid”, or a similar description. Such a description may be considered informal in that it does not refer to the comonomers as copolymerized units; in that it does not include a conventional nomenclature for the copolymer, for example International Union of Pure and Applied Chemistry (IUPAC) nomenclature; in that it does not use product-by-process terminology; or for another reason. As used herein, however, a description of a copolymer with reference to its constituent comonomers or to the amounts of its constituent comonomers means that the copolymer contains copolymerized units (in the specified amounts when specified) of the specified comonomers. It follows as a corollary that a copolymer is not the product of a reaction mixture containing given comonomers in given amounts, unless expressly stated in limited circumstances to be such.

Finally, the materials, methods, and examples herein are illustrative only and, except as specifically stated, are not intended to be limiting.

Described herein is a laminate article with improved anti-spall performance. Specifically, the laminate article comprises a bi-layer composite of a poly(ethylene terephthalate) (PET) film and a polymeric sheet. Suitable PET film has (a) a tensile modulus of about 600,000 psi (about 414 MPa) or higher in both the machine direction (MD) and the transverse direction (TD), (b) a shock brittleness index of about 55 Joules or higher in the MD and about 25 joules or higher in the TD, and (c) a percent elongation at break (EOB) of about 110 to about 160 or about 170 or about 180 in the MD and about 60 to about 110 in the TD. The tensile modulus and the EOB levels are measured in accordance with ASTM D882, while the shock brittleness index is measured in accordance with the test procedure outlined in the Example section, below.

Preferably, the PET film is a bi-axially oriented film. The film may have thickness of about 3 to about 10 mil (about 0.076 to about 0.25 mm) or preferably about 4 to about 7 mils (about 0.1 to about 0.18 mm).

The PET films may be produced by any known process. In the preferred extrusion process, melted PET material is extruded through a slot die and, in the form of a substantially amorphous pre-film, quenched on a chill roll. This amorphous pre-film is then reheated and stretched in MD and subsequently in TD, or in TD and subsequently in MD, or in both MD and TD simultaneously, in a heat oven. Once the stretching is complete, the film is “heat set” or crystallized for about 0.1 to 10 seconds, at a temperature of about 150° C. to about 260° C.

In order to maintain the biaxial orientation and not impart random alignment in a rapid crystallization step, one could adjust the crystallinity temperature to the lower end of this range, so as to obtain a film with a tensile modulus of 600 kpsi and the aforementioned desired physical properties of shock brittleness and EOB. Using a lower crystallization temperature will yield a film with higher shrinkage values. Shrink values are measured after exposing the film to a temperature of 150° C. for 30 minutes. The resulting shrinkage value (about 1% in the MD and TD) is still within the desired range for this application, however. Moreover, shrinkage is also mitigated by the application of the hardcoat to the outside film surface, which restricts the film shrinkage by approximately 40%. It is believed that making such an adjustment to the crystallization temperature is well within the ordinary level of skill in the relevant art. The oriented, heat set PET film is then cooled and wound up in the usual way.

Typical glass/plastic laminates incorporate PET films with higher EOB levels. These PET films tend to have greater flexibility and elasticity; thus, according to theory, the films suffer less splintering upon impact. It has now surprisingly been found, however, that a less elastic PET film (i.e., a film having an EOB of less than 160 or 170 in the MD and less than about 110 in the TD), which also has high tensile strength and high shock brittleness value, may be used. The glass/plastic laminate articles including less elastic PET film in fact suffer less material loss upon high-force impact and therefore exhibit improved impact resistance.

Suitable PET films are preferably surface-treated. By “surface-treated”, it is meant that one surface or both surfaces of the PET film have undergone conditioning to enhance their bonding to the polymeric sheet or to the other film or sheet layers in the laminate article. Such surface-treatments include, without limitation, energy treatments and the application of adhesives or primers. Suitable energy treatments include, without limitation, controlled flame treatment or plasma treatment. Suitable flame treating techniques include, without limitation, those described in U.S. Pat. Nos. 2,632,921; 2,648,097; 2,683,984; and 2,704,382, and suitable plasma treating techniques include, without limitation, those described in U.S. Pat. No. 4,732,814. Suitable adhesives or primers include, without limitation, silanes, poly(alkyl amines), and acrylic based primers.

Examples of suitable silanes include, without limitation, vinyltrieth-oxysilane, vinyltrimethoxysilane, vinyltris(beta-methoxy-ethoxy)silane, γ-methacryloxypropyltrimethoxysilane, β-(3,4-epoxycyclohexyl)ethyl-trimethoxysilane, γ-glycidoxypropyltrimethoxysilane, γ-glycidoxy-propylmethyldiethoxysilane, vinyl-triacetoxysilane, γ-mercaptopropyl-trimethoxysilane, (3-aminopropyl)trimethoxysilane, (3-aminopropyl) triethoxysilane, N-β-(aminoethyl)-γ-aminopropyl-trimethoxysilane, N-(β-aminoethyl)-γ-aminopropylmethyldimethoxysilane, aminoethylamino-propyl silane triol homopolymer, vinylbenzylaminoethylaminopropyl-trimethoxysilane, and mixtures thereof. Preferably, however, the silane used here is an amino-silane, such as, (3-aminopropyl) trimethoxysilane, (3-aminopropyl)triethoxysilane, N-β-(aminoethyl)-γ-aminopropyl-trimethoxysilane, N-(β-aminoethyl)-γ-aminopropylmethyldimethoxysilane, aminoethylaminopropyl silane triol homopolymer, vinylbenzylaminoethyl-aminopropyltrimethoxysilane, bis(trimethoxy-silylpropyl)amine, or mixtures thereof. Commercially available examples of suitable amino-silanes include, for example, DOW CORNING™ Z-6011, Z-6020, Z-6040, Z-6075, Z-6130, Z-6132, Z-6137, Z-6142, Z-6172, Z-6300, and Z-6518 Silane (Dow Corning Corporation, Midland, Mich.) and SILQUEST™ A-151, A-171, A-172, A-187, A-1100, A-1102, A-1110, A-1120, A-1170, and A-2120 Silanes (Momentive Performance Materials, Wilton, Conn.).

Suitable poly(alkylamines) include those derived from α-olefin comonomers having 2 to 10 carbon atoms, such as ethylene, propylene,1-butene, 1 pentene, 1-hexene, 1-heptene, 3 methyl-1-butene, 4-methyl-1-pentene, and mixtures thereof. More particularly, the poly(alkyl amine) may be selected from poly(allylamines) and poly(vinylamines). For example, a linear poly(vinylamine) is available from BASF Corporation of Florham Park, N.J., under the tradename LUPAMIN™ 9095). Preferably, however, the poly(alkylamine) is a poly(allylamine) or a linear poly(allylamine). The poly(allylamine) primer or coating and its application to polyester film surface(s) are described in U.S. Pat. Nos. 5,411,845; 5,770,312; 5,690,994; and 5,698,329.

Acrylic based primers, such as hydroxyacrylic hydrosol primers, are described in U.S. Pat. No. 5,415,942.

The adhesives or primers may be applied through melt processes or through solution, emulsion, dispersion, and other coating processes. One of ordinary skill in the art will be able to identify appropriate process parameters based on the composition and process used for the coating formation. For example, the adhesive or primer composition can be cast, sprayed, air knifed, brushed, rolled, poured or printed onto the film layer surface. Generally the adhesive or primer is diluted with a liquid medium prior to application, to adjust viscosity and to provide uniform coverage over the film surface. The liquid medium may function as a solvent for the adhesive or primer; it may function as a continuous phase in which the adhesive or primer forms a dispersion or emulsion; or it may function as both a solvent and a continuous phase.

The adhesive or primer layer may have a thickness of up to about 10,000 nm, preferably about 0.2 to about 10,000 nm, more preferably about 10 to about 10,000 nm, still more preferably about 10 to about 5,000 nm, still more preferably about 10 to about 1,000 nm, and still more preferably about 10 to about 500 nm.

Preferably, a layer of a poly(alkyl amine) primer, or more preferably a poly(allylamine) primer, is applied to the PET film surface that is adjacent to the polymeric sheet.

Yet more preferably, the PET film may be “hardcoated” with a clear, anti-abrasion coating. Preferably, the hardcoat is coated on the PET film surface that is opposite from the polymeric interlayer sheet. Suitable hardcoat may comprise or be produced from polysiloxanes or cross-linked (thermosetting) polyurethanes. Also suitable are the oligomeric-based coatings described in U.S. Patent Appln. Publn. No. 20050077002, which are prepared by the reaction of a hydroxyl-containing oligomer with an isocyanate-containing oligomer, or by reaction of an anhydride-containing oligomer with an epoxide-containing compound. Preferably, however, the hardcoat is a polysiloxane abrasion resistant coating (PARC), such as those described in U.S. Pat. Nos. 4,177,315; 4,469,743; 5,415,942; and 5,763,089.

To further improve its adhesion to the hardcoat, the PET film surface that receives the hardcoated composition may under go one or more adhesion enhancing treatments, such as those described above, prior to the application of the hardcoat. Preferably, the PET film surface is coated with a layer of an acrylic based primer prior to the application of the hardcoat.

The hardcoat generally has a thickness of up to about 100 μm. Specifically, for those hardcoats comprising or made of polysiloxanes, the thickness may range from about 1 to about 4.5 μm, preferably from about 1.5 to about 3.0 μm, more preferably from about 2.0 to about 2.5 μm, while for those hardcoats comprising or produced from polyurethanes, the thickness may range from about 5 to about 100 μm, or preferably from about 5 to about 50 μm.

In the bi-layer composite, the polymeric sheet may comprise any suitable polymeric material selected from poly(vinyl acetals) (including acoustic grade poly(vinyl acetals)), acid copolymers (i.e., copolymers of α-olefins and α,β-ethylenically unsaturated carboxylic acids), ionomers (i.e., polymers produced by partially or fully neutralizing acid copolymers of α-olefins and α,β-ethylenically unsaturated carboxylic acids), poly(ethylene vinyl acetates), polyurethanes, poly(vinyl chlorides), polyethylenes (e.g., linear low density polyethylenes), polyolefin block elastomers, poly(α-olefin-co-α,β-ethylenically unsaturated carboxylic acid ester) (e.g., poly(ethylene-co-methyl acrylate) and poly(ethylene-co-butyl acrylate), silicone elastomers, epoxy resins, and combinations of two or more thereof. Preferably, the polymeric sheet in the bi-layer composite comprises a poly(vinyl acetal), or more preferably, a poly(vinylbutyral) (PVB).

PVB is a vinyl resin resulting from the condensation of poly(vinyl alcohol) with butyraldehyde and may be produced by aqueous or solvent acetalization. For example, PVB resins can be produced as described in U.S. Pat. Nos. 3,153,009 and 4,696,971.

A suitable PVB preferably has a weight average molecular weight of about 30,000 to about 600,000 Da, more preferably about 45,000 to about 300,000 Da, or still more preferably about 200,000 to about 300,000 Da, as measured by size exclusion chromatography using low angle laser light scattering. The PVB may also contain, on a weight basis, about 12% to about 23%, preferably about 14% to about 21%, more preferably about 15% to about 19.5%, or still more preferably about 15% to about 19%, of hydroxyl groups calculated as poly(vinyl alcohol) (PVOH). The hydroxyl number can be determined according to standard methods, such as ASTM D1396-92. In addition, the PVB may include up to about 10%, or preferably up to about 3% of residual ester groups, calculated as poly(vinyl ester), typically acetate groups. Apart from these copolymerized poly(vinyl alcohol) and poly(vinyl acetate) repeat units, the balance of the repeat units in the PVB are included in the acetal groups. The majority of the acetal groups are butyraldehyde acetal groups; however, the PVB may also contain a minor amount of other acetal groups, e.g., 2-ethyl hexanal, as described in U.S. Pat. No. 5,137,954.

Typically, the PVB composition comprised in the polymeric sheet also comprises one or more plasticizers in an amount that depends on the specific PVB resin and the properties desired in the application. Suitable plasticizers are known in the art and are described in U.S. Pat. Nos. 3,841,890; 4,144,217; 4,276,351; 4,335,036; 4,902,464; 5,013,779 and PCT Patent Application No. WO 96/28504, for example. Plasticizers commonly employed are esters of a polybasic acid or a polyhydric alcohol. Preferred plasticizers include, but are not limited to, diesters obtained by the reaction of triethylene glycol or tetraethylene glycol with aliphatic carboxylic acids having from 6 to 10 carbon atoms, diesters obtained from the reaction of sebacic acid with aliphatic alcohols having from 1 to 18 carbon atoms, oligoethylene glycol di-2-ethylhexanoate, tetraethylene glycol di-n-heptanoate, dihexyl adipate, dioctyl adipate, mixtures of heptyl and nonyl adipates, dibutyl sebacate, tributoxyethylphosphate, isodecylphenylphosphate, triisopropylphosphite, polymeric plasticizers (e.g., oil-modified sebacid alkyds), mixtures of phosphates and adipates, mixtures of adipates and alkyl benzyl phthalates, and combinations of two or more of these plasticizers. More preferred plasticizers include triethylene glycol di-2-ethylhexanoate, tetraethylene glycol di-n-heptanoate, dibutyl sebacate, and combinations of two or more of these plasticizers.

Preferably, the PVB composition incorporates about 15 to about 60 wt %, more preferably about 15 to about 50 wt %, or most preferably about 25 to about 40 wt % of the one or more plasticizers, based on the total weight of the PVB composition.

In one particular polymeric sheet, the PVB composition is an acoustic PVB composition that may contain a single plasticizer in the amount of from about 28 to about 40 wt %. Examples of these acoustic PVB compositions are described in PCT Publication No. WO 2004039581, e.g.

An adhesion control additive, for controlling the adhesive bond between the PVB sheet and the hardcoated PET film or other laminate layers in the safety laminate, e.g., may also be contained in the PVB composition. The adhesion control additives are generally alkali metal or alkaline earth metal salts of organic and inorganic acids. Preferably, they are alkali metal or alkaline earth metal salts of organic carboxylic acids having from 2 to 16 carbon atoms. More preferably, they are magnesium or potassium salts of organic carboxylic acids having from 2 to 16 carbon atoms. Specific examples of suitable adhesion control additives include potassium acetate, potassium formate, potassium propanoate, potassium butanoate, potassium pentanoate, potassium hexanoate, potassium 2-ethylbutylate, potassium heptanoate, potassium octanoate, potassium 2-ethylhexanoate, magnesium acetate, magnesium formate, magnesium propanoate, magnesium butanoate, magnesium pentanoate, magnesium hexanoate, magnesium 2 ethylbutylate, magnesium heptanoate, magnesium octanoate, magnesium 2-ethylhexanoate and the like and combinations of two or more of these salts. The adhesion control additive is typically used in the range of about 0.001 to about 0.5 wt % based on the total weight of the polymeric sheet composition.

Surface tension controlling agents or defoamers, such as Trans™ 290 or 296 (available from the Trans-Chemco Inc., Bristol, Wis.) or Q-23183™ (available from the Dow Chemical Company of Midland, Mich.) may also be included in the PVB composition.

A typical process for the production of a PVB sheet is described herein with the understanding that such a process may be easily modified by one skilled in the art. The plasticized PVB sheets may be formed by initially mixing the PVB resin with plasticizer and then extruding the formulation through a sheet-shaping die, i.e., forcing molten, plasticized PVB through a horizontally long, vertically narrow die opening substantially conforming in length and width to that of the sheet being formed. The plasticized PVB compositions can generally be extruded at a temperature of about 225° C. to about 245° C. Rough surfaces on one or both sides of the extruding sheet are preferably provided by the design of the die opening and the temperature of the die exit surfaces through which the extrudate passes, as described in, e.g., U.S. Pat. No. 4,281,980. Alternative techniques for producing a preferable rough surface on an extruding PVB sheet involve the specification and control of one or more of polymer molecular weight distribution, water content and melt temperature. Various processes for producing PVB sheets are described in U.S. Pat. Nos. 2,904,844; 2,909,810; 3,679,788; 3,994,654; 4,161,565; 4,230,771; 4,292,372; 4,297,262; 4,575,540; 5,151,234; 5,886,675 and European Patent No. EP 0 185 863, for example.

The polymeric sheet (e.g., the PVB sheet) comprised in the bi-layer composite may comprise any other suitable additive(s) that are known in the art. Such additives may include, but are not limited to, processing aids, lubricants, pigments, dyes, flame retardants, impact modifiers, nucleating agents, antiblocking agents (e.g., silica), UV stabilizers, dispersants, surfactants, chelating agents, coupling agents, reinforcement additives (e.g., glass fiber), fillers, and the like. Suitable levels of these additives and methods of incorporating these additives into polymer compositions will be known to those of skill in the art. See, e.g., the Modern Plastics Encyclopedia, McGraw-Hill, New York, N.Y. 1995.

Three particularly useful additives are thermal stabilizers, UV absorbers and hindered amine light stabilizers. Thermal stabilizers have been widely described in the art. Any known thermal stabilizer may find utility in the present invention. Preferred general classes of thermal stabilizers include, but are not limited to, phenolic antioxidants, alkylated monophenols, alkylthiomethylphenols, hydroquinones, alkylated hydroquinones, tocopherols, hydroxylated thiodiphenyl ethers, alkylidenebisphenols, O—, N— and S-benzyl compounds, hydroxybenzylated malonates, aromatic hydroxybenzyl compounds, triazine compounds, aminic antioxidants, aryl amines, diaryl amines, polyaryl amines, acylaminophenols, oxamides, metal deactivators, phosphites, phosphonites, benzylphosphonates, ascorbic acid (vitamin C), compounds that destroy peroxides for example by reacting with the peroxides, hydroxylamines, nitrones, thiosynergists, benzofuranones, indolinones, and the like and mixtures thereof. The polymeric sheet composition may contain any effective amount of one or more thermal stabilizers. Use of a thermal stabilizer is optional and in some instances is not preferred. When used, the polymeric sheet composition may contain at least about 0.05 wt %, and up to about 10 wt %, more preferably up to about 5 wt %, and most preferably up to about 1 wt %, of thermal stabilizer(s), based on the total weight of the composition.

UV absorbers have also been widely described in the art. Any known UV absorber may find utility in the present invention. Preferred general classes of UV absorbers include, but are not limited to, benzotriazoles, hydroxybenzophenones, hydroxyphenyl triazines, esters of substituted and unsubstituted benzoic acids, and the like and mixtures thereof. The polymeric sheet composition may contain any effective amount of one or more UV absorbers. Use of an UV absorber is optional and in some instances is not preferred. When used, the polymeric sheet composition may contain at least about 0.05 wt %, and up about 10 wt %, more preferably up to about 5 wt %, and most preferably up to about 1 wt %, of UV absorber(s), based on the total weight of the composition.

Hindered amine light stabilizers (HALS) are also well known in the art. Generally, hindered amine light stabilizers are described to be secondary, tertiary, acetylated, N hydrocarbyloxy substituted, hydroxy substituted N-hydrocarbyloxy substituted, or other substituted cyclic amines which further incorporate steric hindrance, generally derived from aliphatic substitution on the carbon atoms adjacent to the amine function. The polymeric sheet composition may contain any effective amount of one or more hindered amine light stabilizers. Use of hindered amine light stabilizers is optional and in some instances is not preferred. When used, the polymeric sheet composition may contain at least about 0.05 wt %, and up to about 10 wt %, more preferably up to about 5 wt %, and most preferably, up to about 1 wt %, of hindered amine light stabilizer(s), based on the total weight of the composition.

The polymeric sheet (e.g., the PVB sheet) comprised in the bi-layer composite may have a total thickness of about 10 to about 120 mil (about 0.25 to about 3 mm), preferably about 15 to about 60 mil (about 0.38 to about 1.5 mm), more preferably about 15 to about 30 mil (about 0.38 to about 0.76 mm).

The bi-layer composite may be formed during a lamination process in which the polymeric sheet, the PET film, and the additional laminate layers (if present) are laminated together to form the final laminate article. Preferably, however, that the polymeric sheet and the PET film comprised in the bi-layer composite are bonded into a pre-formed bi-layer composite prior to being further laminated with the other laminate layers.

The processes to pre-form the bi-layer composite may take many forms. In fact, the bi-layer composite may be produced through any known, suitable method. For example, the pre-formed bi-layer composite may be produced through co-extrusion, whereby two or more slit dies are utilized, or by extrusion coating, for example, of the polymeric sheet onto a PET film layer.

Preferably, the pre-formed bi-layer composites are produced through lamination of the polymeric sheets with the PET film layers. For example, the polymeric sheet may be lightly bonded to the PET film layer through a nip roll bonding process. In one example of such a process, the PET film is supplied from a roll and first passed over a tension roll. The PET film may be subjected to moderate heating by passing through a heating zone, such as an oven. The polymeric sheet may also be supplied from a roll or as flat sheet stock and may first be passed over a tension roll. The polymeric sheet may be subjected to moderate heating by passing through a heating zone, such as an oven. Heating should be to a temperature sufficient to promote temporary fusion bonding, i.e., to cause the surfaces of the polymeric sheet to become tacky. Suitable temperatures for a preferred PVB sheet may range from about 50° C. to about 120° C., with the surface temperatures reaching about 65° C.

In a preferred example, where a PVB sheet is included in the bi-layer composite, the PET film layer may be fed along with the PVB sheet through nip rolls where the two layers are merged together under moderate pressure to form a weakly bonded laminate. If desired, the nip rolls may be heated to promote the bonding process. The bonding pressure exerted by the nip rolls may vary with the PVB sheet used or with the temperatures employed. Generally the bonding pressure may be within the range of about 10 to about 75 psi (about 0.7 to about 5.3 kg/cm²), preferably about 25 to about 30 psi (about 1.8 to about 2.1 kg/cm²). The tension between the PVB sheet and the PET film layer, and the tension within these webs, is controlled by passage over one or more idler rolls. Typical line speeds through the roll assembly are within the range of about 5 to about 30 feet (about 1.5 to about 9.2 m) per minute. Proper control of the speed and the tension tends to minimize wrinkling of the film. After bonding, the pre-formed bi-layer composite is passed over a series of cooling rolls which ensure that it is not tacky when taken up on a roll for storage or shipment. Water cooling is generally sufficient to achieve this objective.

Further provided herein is a laminate article, such as a glazing laminate or a solar cell module, comprising the bi-layer composite. The safety glazing and solar cell modules may further include one or more rigid sheets and optionally other polymeric interlayer sheet(s) or additional layers laminated to the bi-layer composite.

The rigid sheets suitable for use herein comprise a material with a modulus of about 100,000 psi (690 MPa) or greater (as measured by ASTM Method D-638). Suitable rigid sheets include, but are not limited to, glass sheets, metal sheets, ceramic sheets, and polymeric sheets derived from polycarbonate, acrylic, polyacrylate, poly(methyl methacrylate), cyclic polyolefins (e.g., ethylene norbornene polymers), polystyrene (preferably metallocene-catalyzed), or the like. When two or more rigid sheets are present in the laminate, they may be the same or different.

Preferably, the rigid sheet is made of glass. The term “glass” as used herein refers not only window glass, plate glass, silicate glass, sheet glass, low iron glass, tempered glass, tempered CeO-free glass, and float glass, but also refers to colored glass, specialty glass (such as those containing ingredients to control solar heating), coated glass (such as those sputtered with metals or metal oxides (e.g., silver or indium tin oxide) for solar control purposes), E-glass, Toroglass, Solex™ glass and Starphire™ glass (available from PPG Industries of Pittsburgh, Pa.). Such specialty glasses are described in, e.g., U.S. Pat. Nos. 4,615,989; 5,173,212; 5,264,286; 6,150,028; 6,340,646; 6,461,736; and 6,468,934. It is understood, however, that the type of glass to be selected for a particular laminate depends on the intended use.

Suitable polymers for use in the additional polymeric interlayer sheets of safety glazing or solar cell modules include, but are not limited to, poly(vinyl acetals) (including acoustic grade poly(vinyl acetals)), acid copolymers, ionomers, poly(ethylene vinyl acetates), polyurethanes, poly(vinyl chlorides), polyethylenes (e.g., linear low density polyethylenes), polyolefin block elastomers, poly(α-olefin-co-α,β-ethylenically unsaturated carboxylic acid ester) (e.g., poly(ethylene-co-methyl acrylate) and poly(ethylene-co-butyl acrylate), silicone elastomers, epoxy resins, and combinations of two or more thereof.

One particular glazing laminate further comprises a rigid sheet (e.g., a glass sheet) that is laminated to the polymeric sheet (e.g., the PVB sheet) of the bi-layer composite. Preferably, the PET film included in the bi-layer composite is hardcoated. Also preferably, the hardcoated PET film is positioned to be facing away from the expected direction of the impact force.

Another glazing laminate further comprises multiple plies of the rigid sheets and multiple plies of the other polymeric interlayer sheets. In this laminate, the rigid sheets are interspaced by the other polymeric sheets and at least one of the rigid sheets is further laminated to the polymeric sheet (e.g., the PVB sheet) of the bi-layer composite. Preferably again, the PET film comprised in the bi-layer composite is hardcoated on the surface that is the outer surface of the laminate. More preferably, the glazing laminate comprises n plies of the glass sheets and n-1 plies of the other polymeric interlayer sheets, wherein (a) 2≦n≦7; (b) the n plies of rigid sheets are interspaced by the n-1 plies of the other polymeric interlayer sheets; and (c) the “(rigid sheet/polymeric interlayer)ₙ₋₁/rigid sheet” composite is further laminated to the polymeric sheet (e.g., the PVB sheet) of the bi-layer composite. When in use, the rigid sheet that is furthest away from the bi-layer composite is positioned to receive the impact force directly. When this construction includes more than one rigid sheet, the rigid sheets may be the same or different. Likewise, when this construction includes more than one other polymeric interlayer sheet, the other polymeric interlayer sheets may be the same or different, and they may be the same as or different from the polymeric sheet of the pre-formed bi-layer composite.

The glazing laminates described herein may be produced through any suitable lamination process. For example, in a conventional autoclave process, the component layers of the glazing laminates are stacked in the desired order to form a pre-lamination assembly. Typically, when one or both of the outer layers of the laminate are polymeric films (e.g., PET films) the pre-lamination assembly may further comprise a rigid cover plate placed over each of the polymeric films. The cover plates may be formed of glass or other suitable rigid materials. Optionally, the pre-lamination assembly may still further comprise a release liner placed between the polymeric film and the rigid cover plate to facilitate de-airing during the lamination process. The release liners used here may be formed of any suitable polymeric material, such as Teflon® films (DuPont) or polyolefin films. The assembly is then placed into a bag capable of sustaining a vacuum (“a vacuum bag”), the air is drawn out of the bag by a vacuum line or other means, the bag is sealed while the vacuum is maintained (e.g., at least about 27-28 in Hg (about 689-711 mm Hg)), and the sealed bag is placed in an autoclave at a pressure of about 150 to about 250 psi (about 11.3 to about 18.8 bar), a temperature of about 130° C. to about 180° C., or about 120° C. to about 160° C., or about 135° C. to about 160° C., or about 145° C. to about 155° C., for about 10 to about 50 minutes, or about 20 to about 45 minutes, or about 20 to about 40 minutes, or about 25 to about 35 minutes. A vacuum ring may be substituted for the vacuum bag. One type of suitable vacuum bag is described in U.S. Pat. No. 3,311,517.

The safety laminates described herein may be used in a variety of end-use applications. For example, the safety laminates may be used in automobile safety glazing (i.e., moonroofs, sidelites, windshields), or in a building as anti-spall window glazing. Hurricane windows in buildings and bullet resistant glazings in armored vehicles are another application for these laminates. Essentially, the safety laminates may be used in any application wherein the favorable properties of glass (integrity and optical clarity) are desired in tandem with anti-spall and/or heightened impact resistance characteristics.

The laminates provided herein may also be used as solar cells. As solar radiation is a sustainable energy resource, the use of solar cells is rapidly expanding. Based on the type of energy converting material that is used, the solar cells can typically be categorized into two categories, specifically, bulk or wafer-based solar cells and thin film solar cells.

Monocrystalline silicon (c-Si), polycrystalline silicon (poly-Si) or multi-crystalline silicon (mc-Si), and ribbon silicon are the materials used most frequently in conventional wafer-based solar cells. Solar cell modules derived from wafer-based solar cells often comprise a series of self-supporting wafers (or cells) that are electrically connected, for example by soldering, and arranged on a flat plane. The cells may have a thickness of about 180 to about 240 μm. Such a series of solar cells is called a solar cell layer. The solar cell layer may further comprise other electrical connections or wiring, such as bus bars running along the flat plane with one end connecting to the cells and the other coming out of the module. The solar cell layer is then further laminated to encapsulant layer(s) or other protective layer(s) to form a weather resistant module. Desirably, the module may have a useful lifetime of up to 25 or 30 years. In general, a solar cell module derived from wafer-based solar cell(s) comprises, counting from the front (light-receiving) side to the back (non-light-receiving) side: (1) an incident layer, (2) a front encapsulant layer, (3) a solar cell layer, (4) a back encapsulant layer, and (5) a backing layer.

In the increasingly important alternative, thin film solar cells, the commonly used energy converting materials include amorphous silicon (a-Si), micro-crystalline silicon (μc-Si), cadmium telluride (CdTe), copper indium selenide (CuInSe₂ or CIS), copper indium/gallium diselenide (CuInₓGa₍₁₋ₓ₎Se₂ or CIGS), light absorbing dyes, organic semiconductors, and the like. By way of example, thin film solar cells are described in U.S. Pat. Nos. 5,507,881; 5,512,107; 5,948,176; 5,994,163; 6,040,521; 6,137,048; and 6,258,620; and in U.S. Patent Appln. Publn. Nos. 20070298590; 20070281090; 20070240759; 20070232057; 20070238285; 20070227578; 20070209699; and 20070079866.

Thin film solar cells with a typical thickness of less than 2 μm are produced by depositing the energy converting layers or cells onto a superstrate or substrate formed of glass or a flexible film. Energy converting layers may be electrically connected by soldering. A laser scribing sequence that enables the adjacent cells to be directly interconnected in series may also be included in the manufacturing process. The laser scribing may take the place of another electrical connection, such as a wire or solder connection, between the cells. The solar cell layer may further comprise other types of electrical connections or wiring, however, such as bus bars, for example. As is set forth above in detail with respect to wafer-based solar cells, the thin film solar cells are further laminated to other encapsulant and protective layers to produce a weather resistant and environmentally robust solar cell module.

In one solar cell module, the thin film solar cell layer comprising the thin film solar cells deposited on the superstrate or substrate is further laminated to two encapsulant layers. This structure is further laminated to two protective layers, one on each surface, to form a weather resistant module.

In another solar cell module, the superstrate, on which the thin film solar cells are deposited, may serve as the incident layer in the final module. Alternatively, the substrate on which the thin film solar cells are deposited may serve as the backing layer in the final module.

More generally, a solar cell module derived from thin film solar cells generally has one of two types of construction. The first type of construction includes, counting from the front (light-receiving) side to the back (non-light-receiving) side, (1) a solar cell layer comprising a superstrate and a layer of thin film solar cell(s) deposited thereon at the non-light-receiving side, (2) a (back) encapsulant layer, and (3) a backing layer. The second type of construction includes, counting from the front side to the back side, (1) an incident layer, (2) a (front) encapsulant layer, (3) a solar cell layer comprising a layer of thin film solar cell(s) deposited on a substrate that also serves as the backing layer on the non-light-receiving side of the module.

The encapsulant layers used in solar cell modules are designed to surround and protect the fragile solar cells. Suitable polymeric materials used in the solar cell encapsulant layers typically possess a combination of desirable characteristics, such as high transparency, low haze, high impact resistance, high penetration resistance, good ultraviolet (UV) light resistance, good long term thermal stability, adequate adhesion strength to glass and other rigid polymeric sheets, high moisture resistance, and good long term weather resistance. In addition, the optical properties of the front encapsulant layer and its interfaces may be such that light can be effectively transmitted to the solar cell layer. For example, the indices of refraction of adjacent layers may be matched or otherwise specially selected for this purpose.

The use of plasticized poly(vinylbutyral) compositions as solar cell encapsulant layers has been described. See, e.g., U.S. Pat. Nos. 3,957,537; 4,249,958; 4,321,418; 5,508,205; 5,582,653; 5,728,230; 6,075,202; 6,288,323; 6,288,326; 6,538,192; 6,777,610; 6,822,157; and 6,940,008; U.S. Patent Appln. Publn. Nos. 20040191422 and 20050284516; and European Patent Nos. 0 343 628; 0 631 328; 1 005 096; and 1 054 456. In addition, in U.S. patent application Ser. No. 11/633,256 (filed on Dec. 4, 2006), a bi-layer composite was described as an encapsulant layer in solar cell modules.

Therefore, with its improved impact resistance properties, the bi-layer composite described herein may also be included in a solar cell module, to further improve the much desired safety aspects of the module.

Specifically, a preferred solar cell module comprises at least one layer of the bi-layer composite and a solar cell layer comprising one or more solar cells. Preferably, the bi-layer composite is laminated to the solar cells at the polymeric sheet side. More preferably, the PET film of the bi-layer composite is hardcoated on the side that is the surface of the module's non-light receiving side.

By “laminated”, it is meant that, within a laminated structure, two layers are adhered or bonded either directly (i.e., without any additional material in between) or indirectly (i.e., with additional material, such as interlayer or adhesive materials, in between the two layers). Other terms that may be used to describe two laminated layers are adjacent, adjoining, or contiguous, again depending on the presence and extent, or absence, of layers or structures that intervene between the two laminated layers.

The term “solar cell”, as used herein, refers to any article that can convert light into electrical energy. Solar cells include, but are not limited to, wafer-based solar cells and thin film solar cells, as described above. Within the solar cell layer, it is preferred that the solar cells be electrically interconnected. In addition, the solar cell layer preferably includes further electrical connections or wiring, such as bus bars.

The solar cell module may further comprise additional encapsulant layers comprising or made of other polymeric materials, such as acid copolymers (i.e., copolymers of α-olefins and α,β-ethylenically unsaturated carboxylic acids), ionomers (i.e., copolymers produced by partially or fully neutralizing acid copolymers of α-olefins and α,β-ethylenically unsaturated carboxylic acids), poly(ethylene vinyl acetates), poly(vinyl acetals) (including acoustic grade poly(vinyl acetals)), polyurethanes, poly(vinyl chlorides), polyethylenes (e.g., linear low density polyethylenes), polyolefin block elastomers, poly(α-olefin-co-α,β-ethylenically unsaturated carboxylic acid ester) (e.g., poly(ethylene-co-methyl acrylate) and poly(ethylene-co-butyl acrylate)), silicone elastomers, epoxy resins, and combinations of two or more thereof. When more than one encapsulant layer is included in a solar cell module, the encapsulant layers may be the same or different, and they may be the same as or different from the polymeric sheet of the pre-formed bi-layer composite.

The thickness of the individual encapsulant layers other than the bi-layer composite may independently be about 1 to about 120 mil (about 0.026 mm to about 3 mm), preferably about 1 to about 40 mil (about 0.026 to about 1.02 mm), or more preferably about 1 to about 20 mil (about 0.026 to about 0.51 mm). All the encapsulant layer(s) comprised in the solar cell modules may have smooth or rough surfaces. Preferably, the encapsulant layer(s) have rough surfaces to facilitate the deaeration of the laminates during the lamination process.

The solar cell module may yet further comprise an incident layer and/or a backing layer serving as the outer most layers of the module at the light-receiving side and the non-light-receiving side, respectively.

The outer layers of the solar cell modules, i.e., the incident layer and the backing layer, may be derived from any suitable sheets or films. Suitable sheets include glass or plastic sheets, such as polycarbonates, acrylics, polyacrylates, cyclic polyolefins (e.g., ethylene norbornene polymers), polystyrenes (preferably metallocene-catalyzed polystyrenes), polyamides, polyesters, fluoropolymers, or combinations of two or more thereof. In addition, metal sheets, such as aluminum, steel, galvanized steel, or ceramic plates may be utilized in forming the backing layer. Suitable films include films made of polymers such as polyesters (e.g., poly(ethylene terephthalate) and poly(ethylene naphthalate)), polycarbonates, polyolefins (e.g., polypropylene, polyethylene, and cyclic polyloefins), norbornene polymers, polystyrenes (e.g., syndiotactic polystyrene), styrene-acrylate copolymers, acrylonitrile-styrene copolymers, polysulfones (e.g., polyethersulfone, polysulfone, etc.), nylons, poly(urethanes), acrylics, cellulose acetates (e.g., cellulose acetate, cellulose triacetates, etc.), cellophanes, poly(vinyl chlorides) (e.g., poly(vinylidene chloride)), fluoropolymers (e.g., polyvinyl fluoride, polyvinylidene fluoride, polytetrafluoroethylene, ethylene-tetrafluoroethylene copolymers, etc.) and combinations of two or more thereof. The polymeric film may be bi-axially oriented polyester film (preferably poly(ethylene terephthalate) film) or a fluoropolymer film (e.g., Tedlar®, Tefzel®, and Teflon® films, available from E. I. du Pont de Nemours and Company, Wilmington, Del. (DuPont)). Multi-layer films, such as a fluoropolymer/polyester/fluoropolymer multilayer film (e.g., the Tedlar® film /PET film/Tedlar® film laminate composite (TPT)) may also be used for some applications. Metal films, such as aluminum foil, may also be used as the backing layer.

The solar cell module may further comprise other functional film or sheet layers (e.g., dielectric layers or barrier layers) embedded within the module. Such functional layers may be derived from any of the above mentioned polymeric films or from those that are coated with additional functional coatings. These other functional film or sheet layers may be the same as or different from the remainder of the films and sheets in the solar cell module. For example, poly(ethylene terephthalate) films coated with a metal oxide coating, such as those described in U.S. Pat. Nos. 6,521,825 and 6,818,819 and in European Patent No. 1182710, may function as oxygen and moisture barrier layers in the laminates.

If desired, a layer of nonwoven glass fiber (scrim) may also be included between the solar cell layers and the encapsulants to facilitate deaeration during the lamination process or to serve as reinforcement for the encapsulants. The use of such scrim layers is described in U.S. Pat. Nos. 5,583,057; 6,075,202; 6,204,443; 6,320,115; 6,323,416; and in European Patent No. 0769818, for example.

The incident layer and the backing layer may be the same as or different from each other. The film or sheet layers positioned at the light-receiving side of the solar cell layer, however, are preferably made of transparent material to allow efficient transmission of sunlight into the solar cells. A special film or sheet may be included to serve both the function of an encapsulant layer and an outer layer. It is also conceivable that any of the film or sheet layers included in the module may be in the form of a pre-formed single-layer or multi-layer film or sheet.

If desired, one or both surfaces of the incident layer films and sheets, the backing layer films and sheets, the encapsulant layers and other layers incorporated within the solar cell module may be treated prior to the lamination process to enhance the adhesion to other laminate layers. This adhesion enhancing treatment may take any form known in the art, including flame treatments (see, e.g., U.S. Pat. Nos. 2,632,921; 2,648,097; 2,683,894; and 2,704,382), plasma treatments (see e.g., U.S. Pat. No. 4,732,814), electron beam treatments, oxidation treatments, corona discharge treatments, chemical treatments, chromic acid treatments, hot air treatments, ozone treatments, ultraviolet light treatments, sand blast treatments, solvent treatments, and combinations of two or more thereof. Also, the adhesion strength may be further improved by further applying an adhesive or primer coating on the surface of the laminate layer(s). For example, U.S. Pat. No. 4,865,711 describes a film or sheet with improved bondability, which has a thin layer of carbon deposited on one or both surfaces. Other suitable adhesives or primers may include silanes, poly(allylamine) based primers (see e.g., U.S. Pat. Nos. 5,411,845; 5,770,312; 5,690,994; and 5,698,329), and acrylic based primers (see e.g., U.S. Pat. No. 5,415,942). The adhesive or primer coating may take the form of a monolayer of the adhesive or primer and may have a thickness of about 0.0004 to about 1 mil (about 0.00001 to about 0.03 mm), or preferably, about 0.004 to about 0.5 mil (about 0.0001 to about 0.013 mm), or more preferably, about 0.004 to about 0.1 mil (about 0.0001 to about 0.003 mm).

When present in a solar cell module, the polymeric sheet of the bi-layer composite may act as an encapsulant layer, more specifically either a front encapsulant layer, a back encapsulant layer, or as the front and back encapsulant layers. Alternatively, the polymeric sheet may act as another functional film or sheet layer. The PET film may act as a barrier layer, as an incident layer, or as a backing layer, or it may fulfill two or more of these three functions. Preferably, the bi-layer composite is present in the solar cell module as the back encapsulant layer and an adjacent barrier layer, or as a back encapsulant layer and an adjacent backing layer.

In one particularly preferred configuration, in which the solar cells are wafer-based self supporting solar cell units, the solar cell module comprises, counting from the front (light-receiving) side to the back (non-light-receiving) side, (a) an incident layer, (b) a front encapsulant layer, (c) a solar cell layer comprised of one or more solar cells electrically interconnected and arranged in a flat plane, and (d) a layer of the bi-layer composite. Preferably, the polymeric sheet side of the bi-layer composite is adjacent to the solar cell layers. More preferably, the PET film of the bi-layer composite is hardcoated on the side that forms the outer surface of back of the module.

In a further preferred configuration, the solar cell modules are thin film solar cells and the module comprises, counting from the front to the back of the module, (a) a solar cell layer comprising a superstrate and a layer of thin film solar cell(s) deposited thereon at the non-light-receiving side and (b) a layer of the bi-layer composite. Here again, it is preferred that the polymeric sheet side of the bi-layer composite be adjacent to the solar cell(s). Once more, it is preferable that the PET film of the bi-layer composite be hardcoated on the side that forms the outer surface of back of the module.

Moreover, the solar cell modules described above may be further linked to other solar cell modules by electrical connections to form a solar cell array. A solar cell array produces a desired voltage and current that is greater than the voltage and current produced by a single solar cell module.

The invention is further described in the Examples below, which are provided to describe the invention in further detail. These examples, which set forth a preferred mode presently contemplated for carrying out the invention, are intended to illustrate and not to limit the invention.

### EXAMPLES

### Example E1 and Comparative Example CE1

In each of example E1 and comparative example CE1, a 12×12 in (305×305 mm) glass/plastic laminate with the following layers was prepared: glass/PVB/PET/hardcoat, wherein the glass was a 90 mil (2.3 mm) thick annealed glass sheet, the PVB was a 30 mil (0.76 mm) thick Butacite® 52J sheet (commercially available from DuPont), the PET was a 7 mil (0.18 mm) PET film as specified in Table 1, and the hardcoat was a 2.3 μm thick layer of a polysiloxane abrasion resistant coating (as described in U.S. Pat. Nos. 4,177,315; 4,469,743; 5,415,942; and 5,763,089) applied on the surface of the PET film that forms the outer surface of the laminate.

TABLE 1

| | | Shock | | | | | |
|---|---|---|---|---|---|---|---|
| | | Brittleness | | Tensile | | Percent | |
| | | Index | | Modulus | | Elongation | |
| | Film | (joules) | | (psi) | | at Break (%) | |
| | Type | MD | TD | MD | TD | MD | TD |
| E1 | PET-1 | 59 | 26 | 613361 | 626233 | 135 | 87 |
| CE1 | PET-2* | 0.7 | 18.8 | 490000 | 510000 | 194 | 135 |

*PET-2 was a Melinex ® 6536 film from DuPont Teijin Films.

These two glass/plastic laminates were further subjected to ANSI Z26.1 test, also known as “Test No. 9”. Briefly, in this test a dart is dropped from a height of 30 ft (9.1 m) onto the glass side of the glass/plastic laminates. In order to pass the test, the dart may not pass through the resulting breach, although the laminate may crack and show signs of puncture. Furthermore, in a passing laminate, no glass spall is released more than 1.5 in (38 mm) from the impact point. Both laminates passed the ANSI test. In Comparative Example CE1, however, the PET film had lower tensile modulus and shock brittleness values. In this laminate, the PET side showed visible splitting after impact at least 80% of the time. In Example E1, in which the PET with improved (higher) physical property values was used, a dramatic reduction in splitting was shown. Moreover, despite the visible post-impact deformation at the PET side of the laminates (e.g., a crater 0.7 cm deep and 2 cm wide), splitting or tearing appeared in less than 20% of the laminates having the same construction as Example E1.

### Examples E2 through E9

### Lamination Process 1:

The component layers of the module structure are stacked to form a pre-lamination assembly. For the assembly containing a polymeric film layer as the outer surface layer, a cover glass sheet is placed over the film layer. The pre-lamination assembly is then placed in a Meier ICOLAM™ 10/08 laminator (Meier Vakuumtechnik GmbH, Bocholt, Germany). The lamination cycle includes an evacuation step (vacuum of 3 in Hg (76 mm Hg)) applied for 5.5 min and a pressing stage (pressure of 1000 mbar) applied for 5.5 min at a temperature of 145° C. The resulting laminate is then removed from the laminator.

### Lamination Process 2:

The component layers of the module structure are stacked to form a pre-lamination assembly. For the assembly containing a polymeric film layer as the outer surface layer, a cover glass sheet is placed over the film layer. The pre-lamination assembly is then placed in a vacuum bag, which is sealed and a vacuum is applied to remove the air from the vacuum bag. The bag is placed into an oven and heated to about 90° C. to about 100° C. for 30 min to remove any air contained between the assembly layers. The assembly is then subjected to autoclaving at 140° C. for 30 min in an air autoclave to a pressure of 200 psig (14.3 bar). The air is cooled while no more air is added to the autoclave. After 20 min of cooling and when the air temperature reaches less than about 50° C., the excess pressure is vented and the vacuum bag containing the laminated assembly is removed from the autoclave. The resulting laminate is then removed from the vacuum bag.

Solar cell modules described below in Table 2 are assembled and laminated by either Lamination Process 1 (E2 to E5) or Lamination Process 2 (E6 to E9). The size of each module is 12×12 in (305×305 mm). Layers 1 and 2 constitute the incident layer and the front-sheet encapsulant layer, respectively, and Layers 4 and 5 constitute the back-sheet encapsulant layer and the backing layer, respectively, where applicable.

TABLE 2

| Example | Solar Cell Laminate Structure | | | | |
|---|---|---|---|---|---|
| No. | Layer 1 | Layer 2 | Layer 3 | Layer 4 | Layer 5 |
| E2, 6 | Glass | ACR | Solar Cell 1 | Bi-layer | |
| E3, 7 | | Bi-layer | Solar Cell 1 | Bi-layer | |
| E4, 8 | | Bi-layer | Solar Cell 1 | ACR | FPF |
| E5, 9 | | | Solar Cell 2 | Bi-layer | |

ACR is a 20 mil (0.51 mm) thick embossed sheet made of poly(ethylene-co-methacrylic acid) containing 18 wt % of polymerized residues of methacrylic acid and having a MI of 2.5 g/10 min (190° C., ISO 1133, ASTM D1238).
FPF is a 1.5 mil (0.038 mm) thick corona surface treated Tedlar ® film from DuPont.
Glass is Starphire ™ glass from PPG Industries.
Bi-layer is a pre-formed bi-layer sheet comprising a 90 mil (2.3 mm) thick Butacite ® 52J sheet (DuPont) bonded to a 7 mil (0.18 mm) thick hardcoated Melinex ® 6536 film (DuPont Teijin Films, Hopewell, VA).
Solar Cell 1 is a silicon solar cell made from a 10 × 10 in (254 × 254 mm) polycrystalline EFG-grown wafer (U.S. Pat. No. 6,660,930, column 7, line 61).
Solar Cell 2 is a thin film solar cell supported on a 12 × 12 in (305 × 305 mm) glass sheet. See, e.g., U.S. Pat. Nos. 5,512,107; 5,948,176; 5,994,163; 6,040,521; 6,137,048; and 6,258,620.

Typically, PET films with higher EOB levels tend to have greater flexibility and elasticity, which would allow the films to suffer less splintering upon impact. In the experiments described above, however, a less elastic PET film, one that has an EOB of less than 160 in the MD and less than about 110 in the TD, which also has high tensile strength and high shock brittleness value, is used in the laminate articles. Surprisingly, it is found that laminates incorporating these less elastic PET films, in fact, suffer less material loss upon high-force impact and therefore exhibit improved impact resistance.

While certain of the preferred embodiments of the present invention have been described and specifically exemplified above, it is not intended that the invention be limited to such embodiments. Various modifications may be made without departing from the scope and spirit of the present invention, as set forth in the following claims.

What is claimed is:

1. A laminate article comprising a bi-layer composite and, optionally, one or more additional laminate layers, wherein
a) the bi-layer composite consists essentially of a polymeric sheet and a poly(ethylene terephthalate) film laminated to each other; and
b) the poly(ethylene terephthalate) film has (i) a tensile modulus of about 600,000 psi or higher in both the machine direction and the transverse direction, (ii) a shock brittleness index of about 55 Joules or higher in the machine direction and about 25 joules or higher in the transverse direction, and (iii) a percent elongation at break (EOB) of about 110 to about 170 in the machine direction and about 60 to about 110 in the transverse direction.

2. The laminate article of claim 1, wherein the poly(ethylene terephthalate) film is a bi-axially oriented poly(ethylene terephthalate) film.

3. The laminate article of claim 1, wherein the poly(ethylene terephthalate) film is a bi-axially oriented poly(ethylene terephthalate) film with a thickness of about 4 to about 7 mil (about 0.1 to about 0.18 mm).

4. The laminate article of claim 1, wherein the poly(ethylene terephthalate) film is further coated with an abrasion resistant hardcoat on the surface that is opposite from the polymeric sheet.

5. The laminate article of claim 4, wherein the abrasion resistant hardcoat comprises or is made from polysiloxanes, cross-linked polyurethanes, or compositions prepared by reacting (a) hydroxyl-containing oligomers with isocyanate-containing oligomers or (b) anhydride-containing oligomers with epoxide-containing compounds.

6. The laminate article of claim 4, wherein the abrasion resistant hardcoat comprises or is made of polysiloxanes.

7. The laminate article of claim 6, wherein the poly(ethylene terephthalate) film is further coated with a poly(allylamine) on the surface that is adjacent to the polymeric sheet.

8. The laminate article of claim 4, wherein the polymeric sheet comprises a poly(vinylbutyral) and a plasticizer and has a thickness of about 15 to about 60 mil (about 0.38 to about 1.5 mm).

9. The laminate article of claim 4, wherein (a) the polymeric sheet comprises a poly(vinylbutyral) and a plasticizer and (b) the poly(ethylene terephthalate) film is coated with (i) a poly(allylamine) on the surface that is adjacent to the polymeric sheet and (ii) an acrylic based primer under the hardcoat.

10. The laminate article of claim 1, wherein at least one surface of the poly(ethylene terephthalate) film is surface-treated and wherein the surface-treatment is (i) an energy treatment or (ii) priming with an adhesive material selected from silanes, poly(alkyl amines), and acrylic based primers.

11. The laminate article of claim 1, wherein the polymeric sheet comprises or is made from a polymeric material selected from the group consisting of poly(vinyl acetals), acid copolymers, ionomers, poly(ethylene vinyl acetates), polyurethanes, poly(vinyl chlorides), polyethylenes, polyolefin block elastomers, poly(α-olefin-co-α,β-ethylenically unsaturated carboxylic acid ester), silicone elastomers, epoxy resins, and combinations of two or more of these materials.

12. The laminate article of claim 11, wherein the poly(vinyl acetal) is a poly(vinylbutyral).

13. The laminate article of claim 12, wherein the polymeric sheet further comprises a plasticizer.

14. The laminate article of claim 1, further comprising at least one rigid sheet, wherein (a) the rigid sheet comprises a material having a modulus of about 100,000 psi (690 MPa) or greater (as measured by ASTM Method D-638), wherein said material is selected from the group consisting of glass sheets, metal sheets, ceramic sheets, and polymeric sheets; and (b) each of the additional polymeric interlayer sheet(s) comprises a polymer selected from the group consisting of poly(vinyl acetals), acid copolymers, ionomers, poly(ethylene vinyl acetates), polyurethanes, poly(vinyl chlorides), polyethylenes, polyolefin block elastomers, poly(α-olefin-co-α,β-ethylenically unsaturated carboxylic acid ester), silicone elastomers, epoxy resins, and combinations of two or more of these materials.

15. The laminate article of claim 14, which consists essentially of one glass sheet that is laminated to the polymeric sheet of the bi-layer composite; and further wherein the poly(ethylene terephthalate) film is hardcoated on the surface that is opposite from the polymeric sheet.

16. The laminate article of claim 14, wherein the at least one rigid sheet is a glass sheet, and wherein the laminate article comprises n plies of the glass sheets and n-1 plies of the additional polymeric interlayer sheets, wherein (a) 2≦n≦7; (b) the n plies of the glass sheets are interspaced by the n-1 plies of the additional polymeric interlayer sheets to form a “(glass/polymer)ₙ₋₁/glass” composite; and (c) the “(glass/polymer)ₙ₋₁/glass” composite is further laminated to the polymeric sheet of the bi-layer composite.

17. The laminate article of claim 1, further comprising a solar cell layer, said solar cell layer comprising one solar cell or a plurality of solar cells that are electrically interconnected; wherein the solar cell has a light-receiving side that faces a light source and a non-light-receiving side that faces away from the light source.

18. The laminate article of claim 17, wherein the laminate further comprises an incident layer and a front encapsulant layer; or a back encapsulant layer and a backing layer; or an incident layer, a front encapsulant layer, a back encapsulant layer and a backing layer; wherein the incident layer and the front encapsulant layer comprise the bi-layer composite; or wherein the back encapsulant layer and the backing layer comprise the bi-layer composite.

19. The laminate article of claim 17, further comprising an incident layer selected from the group consisting of (i) glass sheets, (ii) polymeric sheets comprising or made of polycarbonates, acrylics, polyacrylates, cyclic polyolefins, polystyrenes, polyamides, polyesters, fluoropolymers, or combinations of two or more thereof, and (iii) polymeric films comprising or made of polyesters, polycarbonate, polyolefins, norbornene polymers, polystyrene, styrene-acrylate copolymers, acrylonitrile-styrene copolymers, polysulfones, nylons, polyurethanes, acrylics, cellulose acetates, cellophane, poly(vinyl chlorides), fluoropolymers, or combinations of two or more thereof.

20. The laminate article of claim 17, further comprising a backing layer selected from the group consisting of (i) glass sheets, (ii) polymeric sheets, (iii) polymeric films, (iv) metal sheets, and (v) ceramic plates, and wherein the polymeric sheets comprise or are made of polycarbonates, acrylics, polyacrylates, cyclic polyolefins, polystyrenes, polyamides, polyesters, fluoropolymers, or combinations or two or more thereof; and the polymeric films comprise or are made of polyesters, polycarbonates, polyolefins, norbornene polymers, polystyrenes, styrene-acrylate copolymers, acrylonitrile-styrene copolymers, polysulfones, nylons, polyurethanes, acrylics, cellulose acetates, cellophanes, poly(vinyl chlorides), fluoropolymers, or combinations of two or more thereof.

21. The laminate article of claim 17, wherein the solar cell(s) are wafer-based solar cell(s) selected from the group consisting of crystalline silicon (c-Si) based and multi-crystalline silicone (mc-Si) based solar cells and the laminate article consists essentially of, counting from a front side that faces to the light source to a back side that faces away from the light source, (a) an incident layer, (b) a front encapsulant layer, (c) the solar cell layer, (d) the bi-layer composite with the polymeric sheet being adjacent to the solar cell layer, wherein the PET film is further coated with an abrasion resistance hardcoat on the surface that is opposite from the polymeric sheet.

22. The laminate article of claim 17, wherein the solar cell(s) are thin film solar cells selected from the group consisting of amorphous silicon (a-Si), microcrystalline silicon (μc-Si), cadmium telluride (CdTe), copper indium selenide (CIS), copper indium/gallium diselenide (CIGS), light absorbing dyes, and organic semiconductors based solar cells and the laminate article consists essentially of, counting from a front side that faces the light source to a back side that faces away from the light source, (a) a superstrate; (b) the solar cell layer comprising a layer of the thin film solar cells deposited on the superstrate; and (c) the bi-layer composite with the polymeric sheet being adjacent to the solar cell layer, wherein the poly(ethylene terephthalate) film is further coated with an abrasion resistance hardcoat on the surface that is opposite from the polymeric sheet.
